(19) United States
(12) Patent Application Publication
(10) Pub. No.: US 2013/0116948 A1
(43) Pub. Date: May 9, 2013

(54) SEMICONDUCTOR SYSTEM INCLUDING DATA OUTPUT CIRCUIT

(71) Applicant: Yong Deok CHO, Yongin-si (KR)

(72) Inventor: Yong Deok CHO, Yongin-si (KR)

(73) Assignee: HYNIX SEMICONDUCTOR INC., Icheon-si (KR)

(21) Appl. No.: 13/336,756

(22) Filed: Dec. 23, 2011

(30) Foreign Application Priority Data
Nov. 4, 2011 (KR) 10-2011-0114800

(51) Int. Cl. G06F 19/00; H03K 3/00; G01R 31/3187

(52) U.S. Cl. 702/58; 324/750.3; 327/108

(57) ABSTRACT

A semiconductor system includes a first semiconductor chip configured to perform a parallel test according to a first single chip parallel test signal and a multi-chip parallel test signal, and output first data that indicates if the first semiconductor chip passed or failed. A second semiconductor chip is also configured to perform the parallel test according to a second single chip parallel test signal and the multi-chip parallel test signal, and output second data that indicates if the first semiconductor chip passed or failed.

### CROSS-REFERENCES TO RELATED APPLICATIONS

The present application claims priority under 35 U.S.C 119(a) to Korean Application No. 10-2011-0114800 filed on Nov. 4, 2011 in the Korean intellectual property Office, which is incorporated by reference in its entirety.

### BACKGROUND

There has been a trend in the semiconductor industry toward reduction in size and weight of electronic devices. An example of miniaturization is multi-chip packaging technology. A multi-chip package has an advantage in reduction in size and weight when compared with several single die packages that might otherwise be used.

The multi-chip packaging technology includes a method of stacking a plurality of semiconductor chips and a method of arranging a plurality of semiconductor chip in parallel. In the former method, since the semiconductor chips are stacked, the mounting area may be reduced. In the latter method, since the semiconductor chips are arranged on a plane, the process is simple, and the package is thinner than when stacked. A multi-chip package in which two semiconductor chips are mounted on a lead frame is referred to as a DDP (double die package)-type semiconductor chip package.

Additionally, as semiconductor chips increase in capacity and integration, the chip size increases. Accordingly, a test time is also increased. Most memory cell fails are single bit fails. In order to test for single bit failures, single bits may be sequentially tested. However, this method has a disadvantage in terms of a test time and a test cost. Therefore, there is demand for a test circuit capable of checking whether a semiconductor chip has a single-bit failure within a short time. A circuit to meet that demand is a parallel test circuit. The parallel test is performed by the following process: identical data are preferentially written into all memory cells of a semiconductor chip, a plurality of data among the data stored in the memory cells are read during one access cycle, and a failure of the semiconductor chip is detected by checking whether the read data are identical to the written data.

FIG. 1 is a block diagram illustrating the configuration of a conventional semiconductor system performing a parallel test.

Referring to FIG. 1, the conventional semiconductor system includes a first semiconductor chip 51 and a second semiconductor chip 52. The first semiconductor chip 51 is configured to perform a parallel test and output first data DQ1 as an output signal OUT when a first parallel test signal TPARA1 is applied. The second semiconductor chip 52 is configured to perform a parallel test and output second data DQ2 as the output signal OUT when a second parallel test TPARA2 is applied. The first data DQ1 has a logic high level when the first semiconductor chip 51 is normal as the result of the parallel test for the first semiconductor chip 51, and has a logic low level when the first semiconductor chip 51 fails. Furthermore, the second data DQ2 has a logic high level when the second semiconductor chip 52 is normal as the result of the parallel test for the second semiconductor chip 52, and has a logic low level when the second semiconductor chip 52 fails.

As described above, the first semiconductor chip 51 performs a parallel test according to the first parallel test signal TPARA1, and the second semiconductor chip 52 performs a parallel test according to the second parallel test signal TPARA2. As such, when the parallel tests of the first and second semiconductor chips 51 and 52 are separately performed, the test time inevitably increases, which is insufficient. Therefore, a multi-chip parallel test may be considered. In the multi-chip parallel test, the first and second parallel test signals TPARA1 and TPARA2 are simultaneously applied to perform the parallel tests of the first and second semiconductor chips 51 and 52 at the same time.

However, when the multi-chip parallel test is performed in the conventional semiconductor system, a collision between the first and second data DQ1 and DQ2 may occur to cause an error during the parallel test. That is, when the first semiconductor chip 51 is normal and the second semiconductor chip 52 fails, the high-level first data DQ1 and the low-level data DQ2 collide with each other. Therefore, the output signal OUT does not include valid information regarding the first and semiconductor chips 51 and 52.

### SUMMARY

An embodiment of the present invention relates to a semiconductor system including a data output circuit capable of preventing an operation error by preventing a collision between data in a multi-chip parallel test.

In one embodiment, a semiconductor system includes a first semiconductor chip configured to perform a parallel test according to a first single chip parallel test signal and a multi-chip parallel test signal, and output first data that indicates if the first semiconductor chip passed or failed. A second semiconductor chip is also configured to perform the parallel test according to a second single chip parallel test and the multi-chip parallel test signal, and output second data that indicates if the second semiconductor chip passed or failed. A data receiver may be configured to receive the first and second data as input data.

In another embodiment, a data output circuit includes a driving unit configured to drive data in response to a pull-up signal and a pull-down signal. A pull-up signal generation unit may be configured to generate the pull-up signal from compressed data generated by compressing a plurality of output data, a single chip parallel test signal, and a multi-chip parallel test signal, wherein the pull-up signal is deasserted when a multi-chip parallel test is performed in response to a multi-chip parallel test signal. A pull-down signal generation unit may be configured to generate the pull-down signal from the compressed data and a single chip parallel test signal, wherein the pull-down signal is deasserted when the single-chip parallel test signal is deasserted.

In another embodiment, a method for generating an output signal at a specific chip may include generating a compressed data signal that indicates whether there was a failure in a test of at least a portion of the specific chip. A pull-up signal may be generated from the compressed data signal, a multi-chip test enable signal that is used to indicate to multiple chips to simultaneously run the test, and a single test enable signal that indicates to the specific chip to run the test. A pull-down signal may be generated from the compressed data signal and the single test enable signal. An output signal may be generated from an output circuit controlled by at least the pull-up signal and the pull-down signal.

### BRIEF DESCRIPTION OF THE DRAWINGS

The above and other aspects, features and other advantages will be more clearly understood from the following detailed description taken in conjunction with the accompanying drawings:

FIG. 1 is a block diagram illustrating the configuration of a conventional semiconductor system performing a parallel test;

FIG. 2 is a block diagram illustrating the configuration of an exemplary semiconductor system in accordance with an embodiment of the present invention;

FIG. 3 is a block diagram illustrating an exemplary configuration of a first semiconductor chip included in the semiconductor system of FIG. 1; and

FIG. 4 is a circuit diagram of an exemplary data output unit in the first data output unit of FIG. 3.

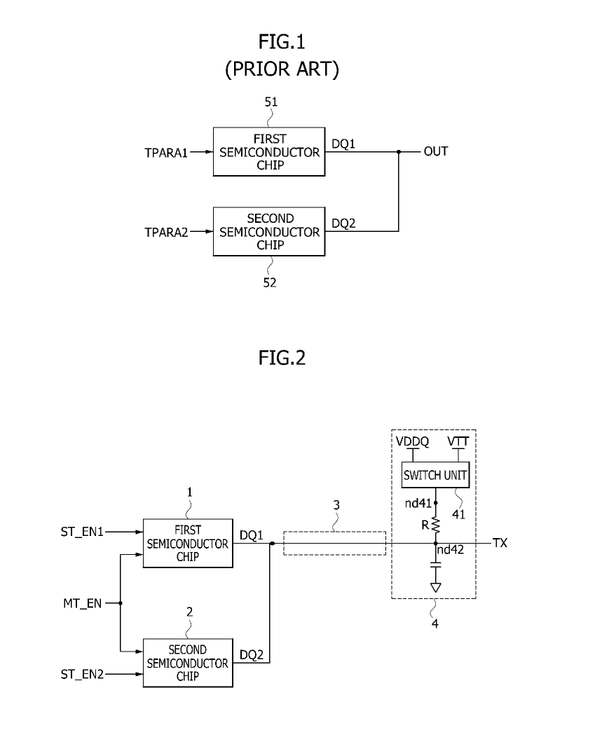

### DESCRIPTION OF SPECIFIC EMBODIMENTS

Embodiments of the present invention will be described with reference to accompanying drawings. However, the embodiments are for illustrative purposes only and are not intended to limit the scope of the invention.

FIG. 2 is a block diagram illustrating the configuration of an exemplary semiconductor system in accordance with an embodiment of the present invention.

Referring to FIG. 2, the semiconductor system in accordance with the embodiment of the present invention includes a first semiconductor chip 1, a semiconductor chip 2, and a data receiver 4. The first semiconductor chip 1 is configured to perform a parallel test and output first data DQ1 in response to a first single chip parallel test signal ST_EN1 and a multi-chip parallel test signal MT_EN. The second semiconductor chip 2 is configured to perform a parallel test and output second data DQ2 in response to a second single chip parallel test signal ST_EN2 and the multi-chip parallel test signal MT_EN. The data receiver 4 is configured to receive the first and second data DQ1 and DQ2 as input data TX through a data channel 3. The first single chip parallel test signal ST_EN1 is enabled to a logic high level when a single chip parallel test is performed on the first semiconductor chip 1, and the second single chip parallel test signal ST_EN2 is enabled to a logic high level when a single chip parallel test is performed on the second semiconductor chip 2. The multi-chip parallel test signal MT_EN is enabled to a logic high level when a multi-chip parallel test is performed on the first and second semiconductor chips 1 and 2.

The data receiver 4 includes a switch unit 41 and a resistor R coupled between a node nd41 and a node nd42. The switch unit 41 is configured to supply a first voltage VTT to the node nd41 when the multi-chip parallel test is not performed, and output a second voltage VDDQ to the node nd41 when the multi-chip parallel test is performed on the first and second semiconductor chips 1 and 2. The first voltage VTT may be set to a half the level of the second voltage VDDQ. The resistor R serves as a termination resistor which receives the voltage of the node nd41 and substantially prevents reflected waves from occurring in an inputted signal due to impedance mismatch. As described above, when the multi-chip parallel test is performed, the second voltage VDDQ is supplied to the node nd41. That is because, since the first and second data DQ1 and DQ2 are generated in a high impedance state when no failure occurs in either of the first and second semiconductor chips 1 and 2, the data receiver 4 generates pulls up the input data TX to a logic high level. However, if either or both of the first and second data DQ1 and DQ2 are in a low state due to a failure, the data receiver 4 enables a wire-OR functionality such that the input data TX is driven low indicating a failure in at least one of the semiconductor chips 1 and 2. If it is desired to identify the specific chip or chips that have failed, then each of the semiconductor chips 1 and 2 may be tested individually.

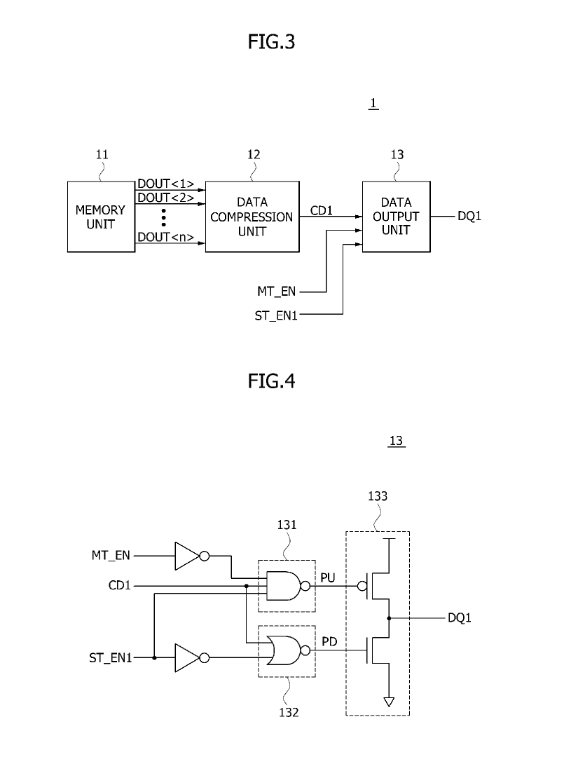

Referring to FIG. 3, the first semiconductor chip 1 includes a memory unit 11, a data compression unit 12, and a data output unit 13. The memory unit 11 is configured to output multi-bit output data DOUT<1:n> when a parallel test including a single chip parallel test and a multi chip parallel test is performed. The data compression unit 12 is configured to compress the output data DOUT<1:n> and generate first compressed data CD1. The data output unit 13 is configured to receive the first compressed data CD1 and generate and output the first data DQ1 in response to the first single chip parallel test signal ST_EN1 and the multi-chip parallel test signal MT_EN.

Referring to FIG. 4, the data output unit 13 includes a pull-up signal generation section 131, a pull-down signal generation section 132, and a driving section 133. The pull-up signal generation section 131 is configured to receive a signal obtained by inverting and buffering the multi-chip parallel test signal MT_EN, the first compressed data CD1, and the first single chip parallel test signal ST_EN1, and perform a NAND operation on the received signals to generate a pull-up signal PU. The pull-down signal generation section 132 is configured to receive the first compressed data CD1 and a signal obtained by inverting and buffering the first single chip parallel test signal ST_EN1, and perform a NOR operation on the received signals to generate a pull-down signal PD. The driving section 133 is configured to drive the first data DQ1 in response to the pull-up signal PU and the pull-down signal PD.

Accordingly, when the multi-chip parallel test signal MT_EN is asserted to a high level, the pull-up signal PU is at a high level. When the first compressed data CD1 is at a high level, indicating no failure, pull-down signal PD is at a low level. Therefore, since driving section 133 is disabled, the first semiconductor chip 1 generates the first data DQ1 in a high impedance state. Furthermore, when a fail occurs, the first semiconductor chip 1 drives the first data DQ1 to a logic low level according to the low-level first compressed data CD1. Meanwhile, when a single chip parallel test is performed, the first semiconductor chip 1 buffers the first compressed data CD1 according to the high-level first single chip parallel test signal ST_EN1, and generates the pull-up signal PU and the pull-down signal PD. Therefore, the first semiconductor chip 1 generates high-level first data DQ1 when no failure occurs in the single chip parallel test, and generates low-level second data DQ2 when a failure occurs.

The second semiconductor chip 2 has a similar configuration to the first semiconductor chip 1, except that it receives a second single chip parallel test signal ST_EN2 and generates second data DQ2. The detailed descriptions thereof are omitted.

The parallel test operation of the semiconductor system configured in such a manner will be described in detail. The parallel test operation may be divided into a case in which a single chip parallel test is performed on the first semiconductor chip 1, a case in which a single chip parallel test is performed on the second semiconductor chip 2, and a case in which a multi-chip parallel test is performed on the first and second semiconductor chips 1 and 2.

First, when a single chip parallel test is performed on the first semiconductor chip 1, the first single chip parallel test signal ST_EN1 is enabled to a logic high level, and the second single chip parallel test signal ST_EN2 and the multi-chip parallel test signal MT_EN are disabled to a logic low level. Therefore, through the single chip parallel test, the first semiconductor chip 1 generates the first data DQ1 in a high-impedance state that is pulled-up by the data receiver 4 when no fail occurs, and generates low-level first data DQ1 when a fail occurs. The second data DQ2 of the second semiconductor chip 2 is at a high-output state, and, accordingly, has no impact on the output of the first data DQ1 of the first semiconductor chip 1.

Next, when a single chip parallel test is performed on the second semiconductor chip 2, the second single chip parallel test signal ST_EN2 is enabled to a logic high level, and the first single chip parallel test signal ST_EN1 and the multi-chip parallel test signal MT_EN are disabled to a logic low level. Therefore, through the single chip parallel test, the first semiconductor chip 2 generates the second data DQ2 in a high-impedance state that is pulled up by the data receiver 4 when no fail occurs, and generates low-level second data DQ2 when a fail occurs. The first data DQ1 of the first semiconductor chip 1 is at a high-output state, and, accordingly, has no impact on the output of the second data DQ2 of the second semiconductor chip 2.

Finally, when a multi-chip parallel test is performed on the first and second semiconductor chips 1 and 2, the multi-chip parallel test signal MT_EN is enabled to a logic high level, and the first and second single chip parallel test signal ST_EN1 and ST_EN2 are asserted to a logic high level. The high-level multi-chip parallel test signal MT_EN disables the pull-up signal PU to a logic high level. Therefore, when no fail occurs in the first semiconductor chip 1, the first data DQ1 is generated in a high impedance state, and when no fail occurs in the second semiconductor chip 2, the second data DQ2 is generated in a high impedance state. When a failure occurs in the first semiconductor chip 1, the first data DQ1 is generated at a logic low level, and when a fail occurs in the second semiconductor chip 2, the second data DQ2 is generated at a logic low level. Regardless of the state of the other data, if one of the first data DQ1 or the second data DQ2 is low, the input data TX is driven low.

When the multi-chip parallel test is performed, the semiconductor system in accordance with an embodiment of the present invention generates data places output in a high-impedance state when no failure occurs. This prevents an operation error caused by a collision between data. That is, when no failure occurs in the first semiconductor chip 1 and a failure occurs in the second semiconductor chip 2, the first data DQ1 is generated in a high impedance state, and the second data DQ2 is driven at a logic low level. Therefore, the data receiver 4 may receive the low-level second data DQ2 as the input data TX without an error.

The embodiments of the present invention have been disclosed above for illustrative purposes. Those skilled in the art will appreciate that various modifications, additions, and substitutions are possible, without departing from the scope and spirit of the invention as disclosed in the accompanying claims.

What is claimed is:

1. A semiconductor system comprising:
a first semiconductor chip configured to perform a parallel test according to a first single chip parallel test signal and a multi-chip parallel test signal, and output first data indicating pass or fail;
a second semiconductor chip configured to perform a parallel test according to a second single chip parallel test signal and the multi-chip parallel test signal, and output second data indicating pass or fail information; and
a data receiver configured to receive the first and second data as input data.

2. The semiconductor system of claim 1, wherein the first data is output in a high impedance state when the first semiconductor chip is normal.

3. The semiconductor system of claim 1, wherein the second data is output in a high impedance state when the second semiconductor chip is normal.

4. The semiconductor system of claim 1, wherein the data receiver comprises:
a switch unit configured to supply a first voltage to a first node, and supply a second voltage to the first node when a multi-chip parallel test is performed; and
a resistor coupled between the first node and a second node, wherein the input data is received.

5. The semiconductor system of claim 1, wherein the first semiconductor chip comprises:
a data compression unit configured to compress a plurality of data outputted from the memory unit and generate compressed data when a single chip parallel test or multi-chip parallel test is performed; and
a data output unit configured to generate a first pull-up signal and a first pull-down signal from the compressed data to drive the first data, in response to at least one of the first single chip parallel test signal and the multi-chip parallel test signal.

6. The semiconductor system of claim 5, wherein the first pull-up signal is disabled to a high level by the multi-chip parallel test signal when a multi-chip parallel test is performed.

7. The semiconductor system of claim 5, wherein the data output unit comprises:
a pull-up signal generation section configured to generate the first pull-up signal in response to the compressed data, first single chip parallel test signal, and the multi-chip parallel test signal;
a pull-down signal generation section configured to generate the first pull-down signal in response to the compressed data and the first single chip parallel test signal; and
a driving section configured to drive the first data in response to the first pull-up signal and the first pull-down signal.

8. The semiconductor system of claim 1, wherein the second semiconductor chip comprises:
a data compression unit configured to compress a plurality of data outputted from the memory unit and generate compressed data, when a single chip parallel test or multi-chip parallel test is performed; and
a data output unit configured to generate a second pull-up signal and a second pull-down signal from the compressed data to drive the second data, in response to at least one of the second single chip parallel test signal and the multi-chip parallel test signal.

9. The semiconductor system of claim 8, wherein the second pull-up signal is disabled to a high level by the multi-chip parallel test signal when a multi-chip parallel test is performed.

10. The semiconductor system of claim 8, wherein the data output unit comprises:
a pull-up signal generation section configured to generate the second pull-up signal in response to the compressed data, the second single chip parallel test signal, and the multi-chip parallel test signal;
a pull-down signal generation section configured to generate the second pull-down signal in response to the compressed data and the second single chip parallel test signal; and
a driving section configured to drive the second data in response to the second pull-up signal and the second pull-down signal.

11. A data output circuit comprising:
a driving unit configured to drive data in response to a pull-up signal and a pull-down signal;
a pull-up signal generation unit configured to generate the pull-up signal from compressed data generated by compressing a plurality of output data, a single chip parallel test signal, and a multi-chip parallel test signal,
wherein the pull-up signal is deasserted when a multi-chip parallel test is performed in response to a multi-chip parallel test signal; and
a pull-down signal generation unit configured to generate the pull-down signal from the compressed data and a single chip parallel test signal, wherein the pull-down signal is deasserted when the single-chip parallel test signal is deasserted.

12. The data output circuit of claim 11, wherein the pull-up signal is asserted when the compressed data indicates success, the single chip parallel test signal is asserted, and the multi-chip parallel test signal is asserted.

13. The data output circuit of claim 11, wherein the pull-down signal is asserted when the compressed data indicates failure and the single chip parallel test signal is asserted.

14. A method for generating an output signal at a specific chip, comprising:
generating a compressed data signal that indicates whether there was a failure in a test of at least a portion of the specific chip;
generating a pull-up signal from the compressed data signal, a multi-chip test enable signal that is used to indicate to multiple chips to simultaneously run the test, and a single test enable signal that indicates to the specific chip to run the test;
generating a pull-down signal from the compressed data signal and the single test enable signal; and
generating an output signal from an output circuit controlled by at least the pull-up signal and the pull-down signal.

15. The method according to claim 14, comprising asserting the pull-up signal when the multi-chip test enable signal is asserted, the compressed data signal indicates that there is no failure, and the single chip test enable signal is asserted.

16. The method according to claim 14, comprising asserting the pull-down signal when the single chip test enable signal is asserted and the compressed data signal indicates that there is no failure.

17. The method according to claim 14, wherein the pull-up signal and the pull-down signal controls the output circuit.

18. The method according to claim 17, wherein the output circuit is in a high-impedance output state when the pull-up signal and the pull-down signal are both deasserted.
